(19) United States
(12) Patent Application Publication
(10) Pub. No.: US 2023/0168049 A1
(43) Pub. Date: Jun. 1, 2023

(54) HEAT-DISSIPATION SUBSTRATE STRUCTURE WITH HIGH ADHESIVE STRENGTH

(71) Applicant: AMULAIRE THERMAL TECHNOLOGY, INC., New Taipei City (TW)

(72) Inventors: TSUNG-RUEI SUEI, New Taipei City (TW); TZE-YANG YEH, New Taipei City (TW); MIN-HORNG LIU, New Taipei City (TW)

(21) Appl. No.: 17/539,539

(22) Filed: Dec. 1, 2021

(51) Int. Cl. F28F 13/18; F28F 21/08; C23C 14/34

(52) U.S. Cl. CPC F28F 13/185; F28F 21/089; C23C 14/34; F28F 2245/06; F28F 2260/00; F28F 2275/025; F28F 21/086; F28F 21/087; F28F 21/084; F28F 21/085

(57) ABSTRACT

A heat-dissipation substrate structure with high adhesive strength is provided. The heat-dissipation substrate structure includes a heat-dissipation base layer, a functional layer, and a matching layer. The functional layer is formed by sputtering, and has a single layer structure or a multi-layer structure. A thickness of each layer of the functional layer is less than 3 μm. The matching layer has a single layer structure or a multi-layer structure, and a thickness of each layer of the multi-layer structure of the matching layer is less than 1 μm. The matching layer is formed by sputtering of one or any two of titanium, titanium alloy, nickel, and nickel alloy. The functional layer and the heat-dissipation base layer are two heterogeneous metal layers, and the matching layer is located between the functional layer and the heat-dissipation base layer.

### FIELD OF THE DISCLOSURE

The present disclosure relates to a heat-dissipation substrate structure, and more particularly to a heat-dissipation substrate structure with high adhesive strength.

### BACKGROUND OF THE DISCLOSURE

In the related art, a functional layer can be formed on a surface of a conventional heat-dissipation substrate by sputtering, so as to increase functional properties provided by said surface. However, the functional layer and the heat-dissipation substrate are formed by heterogeneous metals. As a result, when a product is used under high temperature and high pressure, an adhesive property between the functional layer and the heat-dissipation substrate is poor, thereby causing a product life to decrease significantly.

### SUMMARY OF THE DISCLOSURE

In response to the above-referenced technical inadequacy, the present disclosure provides a heat-dissipation substrate structure with high adhesive strength.

In one aspect, the present disclosure provides a heat-dissipation substrate structure with high adhesive strength. The heat-dissipation substrate structure includes a heat-dissipation base layer, a functional layer, and a matching layer configured for improving an adhesive property between the heat-dissipation base layer and the functional layer. The functional layer is formed by sputtering, and has at least one of a corrosion resistance property, a soldering property, and a sintering property. The functional layer has a single layer structure or a multi-layer structure, and a thickness of each layer of the single layer structure or the multi-layer structure of the function layer is less than 3 μm. The matching layer has a single layer structure or a multi-layer structure, and a thickness of each layer of the single layer structure or the multi-layer structure of the matching layer is less than 1 μm. The matching layer is formed by sputtering of one or any two of titanium, titanium alloy, nickel, and nickel alloy. The functional layer and the heat-dissipation base layer are two heterogeneous metal layers, and the matching layer is located between the functional layer and the heat-dissipation base layer, so as to improve the adhesive property between the heat-dissipation base layer and the functional layer.

In certain embodiments, the heat-dissipation base layer is formed by one of aluminum and aluminum alloy. The functional layer is a sputtered copper layer formed by sputtering of copper or copper alloy. The functional layer and the heat-dissipation base layer are two heterogeneous metal layers, and the matching layer located between the functional layer and the heat-dissipation base layer is formed by sputtering of one of titanium, titanium alloy, nickel, and nickel alloy.

In certain embodiments, the heat-dissipation base layer is formed by one of copper, copper alloy, aluminum, and aluminum alloy. The functional layer is a sputtered nickel layer formed by sputtering of nickel or nickel alloy. The functional layer and the heat-dissipation base layer are two heterogeneous metal layers, and the matching layer located between the functional layer and the heat-dissipation base layer is formed by sputtering of one of titanium and titanium alloy.

In certain embodiments, the heat-dissipation base layer is formed by one of copper, copper alloy, aluminum, and aluminum alloy. The functional layer is a sputtered silver layer formed by sputtering of silver or silver alloy. The functional layer and the heat-dissipation base layer are two heterogeneous metal layers, and the matching layer located between the functional layer and the heat-dissipation base layer is formed by sputtering of nickel or both nickel and titanium.

In certain embodiments, the heat-dissipation base layer is formed by one of copper, copper alloy, aluminum, and aluminum alloy. The functional layer is a sputtered tin layer formed by sputtering of tin or tin alloy. The functional layer and the heat-dissipation base layer are two heterogeneous metal layers, and the matching layer located between the functional layer and the heat-dissipation base layer is formed by sputtering of one of titanium, titanium alloy, nickel and nickel alloy.

In certain embodiments, the matching layer and the functional layer are formed under a vacuum condition where a vacuum degree is less than 10⁻² mbar.

In certain embodiments, the matching layer and the functional layer are formed under a condition where a sputtering power is equal to or greater than 1000 W.

Therefore, in the heat-dissipation substrate structure with high adhesive strength provided by the present disclosure, by virtue of “the heat-dissipation substrate structure including a heat-dissipation base layer, a functional layer, and a matching layer configured for improving an adhesive property between the heat-dissipation base layer and the functional layer,” “the functional layer being formed by sputtering and having at least one of a corrosion resistance property, a soldering property, and a sintering property,” “the functional layer having a single layer structure or a multi-layer structure, and a thickness of each layer of the single layer structure or the multi-layer structure of the functional layer being less than 3 μm,” “the matching layer having a single layer structure or a multi-layer structure, and a thickness of each layer of the single layer structure or the multi-layer structure of the matching layer being less than 1 μm,” and “the matching layer being formed by sputtering of one or any two of titanium, titanium alloy, nickel, and nickel alloy, the functional layer and the heat-dissipation base layer being two heterogeneous metal layers, and the matching layer being located between the functional layer and the heat-dissipation base layer,” the adhesive property between the heat-dissipation base layer and the functional layer can be effectively improved, thereby significantly increasing a product life.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic side view of a heat-dissipation substrate structure with high adhesive strength according to an embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

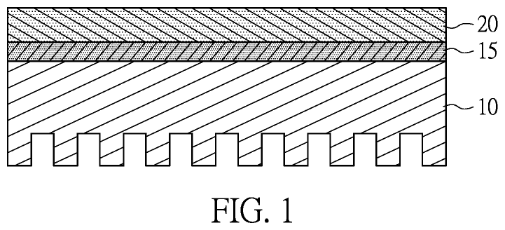

Referring to FIG. 1, an embodiment of the present disclosure provides a heat-dissipation substrate structure with high adhesive strength. As shown in the drawing, in the present embodiment, the heat-dissipation substrate structure with high adhesive strength includes a heat-dissipation base layer 10, a functional layer 20, and a matching layer 15 configured for improving an adhesive property between the heat-dissipation base layer 10 and the functional layer 20.

The heat-dissipation base layer 10 can be formed by copper, copper alloy, aluminum or aluminum alloy. The functional layer 20 can be formed by copper, copper alloy, nickel, nickel alloy, tin, tin alloy, silver or silver alloy. In order to increase functional properties of a surface, the functional layer 20 and the heat-dissipation base layer 10 need to be formed by two heterogeneous metals. In addition, in order to improve the adhesive property between the functional layer 20 and the heat-dissipation base layer 10, the matching layer 15 needs to be formed between the functional layer 20 and the heat-dissipation base layer 10.

In continuation of the above, the functional layer 20 can have a single layer structure or a multi-layer structure, and a thickness of each layer of the single layer structure or the multi-layer structure of the function layer 20 is less than 3 μm. The matching layer 15 can have a single layer structure or a multi-layer structure, and a thickness of each layer of the single layer structure or the multi-layer structure of the matching layer 15 is less than 1 μm. The matching layer 15 is formed by sputtering of one or any two of titanium, titanium alloy, nickel, and nickel alloy.

In an exemplary embodiment, the heat-dissipation base layer 10 can be formed by copper, copper alloy, aluminum or aluminum alloy. The functional layer 20 is a sputtered nickel layer formed by sputtering of nickel or nickel alloy. Therefore, the functional layer 20 has a corrosion resistance property. Further, the functional layer 20 and the heat-dissipation base layer 10 are two heterogeneous metal layers, and the matching layer 15 located between the functional layer 20 and the heat-dissipation base layer 10 is formed by sputtering of titanium or titanium alloy. In this way, adhesive strength between the matching layer 15 and the heat-dissipation base layer 10 is better than that between the functional layer 20 and the heat-dissipation base layer 10. Moreover, adhesive strength between the matching layer 15 and the functional layer 20 is also better than that between the functional layer 20 and the heat-dissipation base layer 10. Consequently, the adhesion property between the functional layer 20 and the heat-dissipation base layer 10 can be improved by the matching layer 15.

In an exemplary embodiment, the heat-dissipation base layer 10 can be formed by aluminum or aluminum alloy. The functional layer 20 is a sputtered copper layer formed by sputtering of copper or copper alloy. Therefore, the functional layer 20 has a soldering property. Further, the functional layer 20 and the heat-dissipation base layer 10 are two heterogeneous metal layers, and the matching layer 15 located between the functional layer 20 and the heat-dissipation base layer 10 is formed by sputtering of titanium, titanium alloy, nickel or nickel alloy. In this way, the adhesive strength between the matching layer 15 and the heat-dissipation base layer 10 is better than that between the functional layer 20 and the heat-dissipation base layer 10. Moreover, the adhesive strength between the matching layer 15 and the functional layer 20 is also better than that between the functional layer 20 and the heat-dissipation base layer 10. Consequently, the adhesion property between the functional layer 20 and the heat-dissipation base layer 10 can be improved by the matching layer 15.

In an exemplary embodiment, the heat-dissipation base layer 10 can be formed by copper, copper alloy, aluminum or aluminum alloy. The functional layer 20 is a sputtered silver layer formed by sputtering of silver or silver alloy. Therefore, the functional layer 20 has a sintering property. Further, the functional layer 20 and the heat-dissipation base layer 10 are two heterogeneous metal layers, and the matching layer 15 located between the functional layer 20 and the heat-dissipation base layer 10 is formed by sputtering of nickel or both nickel and titanium. In this way, the adhesive strength between the matching layer 15 and the heat-dissipation base layer 10 is better than that between the functional layer 20 and the heat-dissipation base layer 10. Moreover, the adhesive strength between the matching layer 15 and the functional layer 20 is also better than that between the functional layer 20 and the heat-dissipation base layer 10. Consequently, the adhesion property between the functional layer 20 and the heat-dissipation base layer 10 can be improved by the matching layer 15.

In an exemplary embodiment, the heat-dissipation base layer 10 can be formed by copper, copper alloy, aluminum or aluminum alloy. The functional layer 20 is a sputtered tin layer formed by sputtering of tin or tin alloy. Therefore, the functional layer 20 has the corrosion resistance property and the soldering property. Further, the functional layer 20 and the heat-dissipation base layer 10 are two heterogeneous metal layers, and the matching layer 15 located between the functional layer 20 and the heat-dissipation base layer 10 is formed by sputtering of titanium, titanium alloy, nickel or nickel alloy. In this way, the adhesive strength between the matching layer 15 and the heat-dissipation base layer 10 is better than that between the functional layer 20 and the heat-dissipation base layer 10. Moreover, the adhesive strength between the matching layer 15 and the functional layer 20 is also better than that between the functional layer 20 and the heat-dissipation base layer 10. Consequently, the adhesion property between the functional layer 20 and the heat-dissipation base layer 10 can be improved by the matching layer 15.

In an exemplary embodiment, in order to improve the adhesive property between the functional layer 20 and the heat-dissipation base layer 10, the matching layer 15 and the functional layer 20 are formed under a vacuum condition where a vacuum degree is less than 10⁻² mbar. In addition, the matching layer 15 and the functional layer 20 are formed under a condition where a sputtering power is equal to or greater than 1000 W.

[Beneficial Effects of the Embodiment]

In conclusion, in the heat-dissipation substrate structure with high adhesive strength provided by the present disclosure, by virtue of “the heat-dissipation substrate structure including a heat-dissipation base layer, a functional layer, and a matching layer configured for improving an adhesive property between the heat-dissipation base layer and the functional layer,” “the functional layer being formed by sputtering and having at least one of a corrosion resistance property, a soldering property, and a sintering property,” “the functional layer having a single layer structure or a multi-layer structure, and a thickness of each layer of the single layer structure or the multi-layer structure of the functional layer being less than 3 μm,” “the matching layer having a single layer structure or a multi-layer structure, and a thickness of each layer of the single layer structure or the multi-layer structure of the matching layer being less than 1 μm,” and “the matching layer being formed by sputtering of one or any two of titanium, titanium alloy, nickel, and nickel alloy, the functional layer and the heat-dissipation base layer being two heterogeneous metal layers, and the matching layer being located between the functional layer and the heat-dissipation base layer,” the adhesive property between the heat-dissipation base layer and the functional layer can be effectively improved, thereby significantly increasing a product life.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A heat-dissipation substrate structure with high adhesive strength, comprising:
a heat-dissipation base layer;
a functional layer; and
a matching layer configured for improving an adhesive property between the heat-dissipation base layer and the functional layer;
wherein the functional layer is formed by sputtering, and has at least one of a corrosion resistance property, a soldering property, and a sintering property;
wherein the functional layer has a single layer structure or a multi-layer structure, and a thickness of each layer of the single layer structure or the multi-layer structure of the functional layer is less than 3 μm;
wherein the matching layer has a single layer structure or a multi-layer structure, and a thickness of each layer of the single layer structure or the multi-layer structure of the matching layer is less than 1 μm;
wherein the matching layer is formed by sputtering of one or any two of titanium, titanium alloy, nickel, and nickel alloy;
wherein the functional layer and the heat-dissipation base layer are two heterogeneous metal layers, and the matching layer is located between the functional layer and the heat-dissipation base layer, so as to improve the adhesive property between the heat-dissipation base layer and the functional layer.

2. The heat-dissipation substrate structure according to claim 1, wherein the heat-dissipation base layer is formed by one of aluminum and aluminum alloy; wherein the functional layer is a sputtered copper layer formed by sputtering of copper or copper alloy; wherein the functional layer and the heat-dissipation base layer are two heterogeneous metal layers, and the matching layer located between the functional layer and the heat-dissipation base layer is formed by sputtering of one of titanium, titanium alloy, nickel, and nickel alloy.

3. The heat-dissipation substrate structure according to claim 1, wherein the heat-dissipation base layer is formed by one of copper, copper alloy, aluminum, and aluminum alloy; wherein the functional layer is a sputtered nickel layer formed by sputtering of nickel or nickel alloy; wherein the functional layer and the heat-dissipation base layer are two heterogeneous metal layers, and the matching layer located between the functional layer and the heat-dissipation base layer is formed by sputtering of one of titanium and titanium alloy.

4. The heat-dissipation substrate structure according to claim 1, wherein the heat-dissipation base layer is formed by one of copper, copper alloy, aluminum, and aluminum alloy; wherein the functional layer is a sputtered silver layer formed by sputtering of silver or silver alloy; wherein the functional layer and the heat-dissipation base layer are two heterogeneous metal layers, and the matching layer located between the functional layer and the heat-dissipation base layer is formed by sputtering of nickel or both nickel and titanium.

5. The heat-dissipation substrate structure according to claim 1, wherein the heat-dissipation base layer is formed by one of copper, copper alloy, aluminum, and aluminum alloy; wherein the functional layer is a sputtered tin layer formed by sputtering of tin or tin alloy; wherein the functional layer and the heat-dissipation base layer are two heterogeneous metal layers, and the matching layer located between the functional layer and the heat-dissipation base layer is formed by sputtering of one of titanium, titanium alloy, nickel and nickel alloy.

6. The heat-dissipation substrate structure according to claim 1, wherein the matching layer and the functional layer are formed under a vacuum condition where a vacuum degree is less than 10⁻² mbar.

7. The heat-dissipation substrate structure according to claim 1, wherein the matching layer and the functional layer are formed under a condition where a sputtering power is equal to or greater than 1000 W.
